(19) United States
(12) Patent Application Publication
(10) Pub. No.: US 2017/0089360 A1
(43) Pub. Date: Mar. 30, 2017

(54) Fan Including an Acoustic Absorption Member in Contact and Movable with Vanes

(71) Applicant: HEWLETT-PACKARD DEVELOPMENT COMPANY, L.P., HOUSTON, TX (US)

(72) Inventors: CHIENLUNG YANG, HOUSTON, TX (US); KUAN-TING WU, TAIPEI CITY (TW); HUI LENG LIM, HOUSTON, TX (US)

(73) Assignee: HEWLETT- PACKARD DEVELOPMENT COMPANY, L.P., HOUSTON, TX (US)

(21) Appl. No.: 15/306,520

(22) PCT Filed: Jun. 18, 2014
(86) PCT No.: PCT/US14/42858

§ 371 Date: Oct. 25, 2016

(51) Int. Cl. F04D 29/66; G06F 1/20; H05K 7/20; F04D 29/32

(52) U.S. Cl. CPC F04D 29/664; F04D 29/326; G06F 1/20; H05K 7/20172

(57) ABSTRACT

A fan includes a main member, vanes, and an acoustic absorption member. The vanes are coupled to and extending outward from the main member. The acoustic absorption member is coupled to each one of the plurality of vanes. The acoustic absorption member and the vanes rotate along with the main member.

### BACKGROUND

Computing devices generate heat while in operation. The temperature of the computing devices may increase with higher processing speeds and additional processing tasks. The computing devices may include fans to generate and direct air flow to reduce the heat therein. The fans may reduce the temperature of the computing devices to enable user comfort, high processing speeds, and additional processing tasks.

### BRIEF DESCRIPTION OF THE DRAWINGS

Non-limiting examples are described in the following description, read with reference to the figures attached hereto and do not limit the scope of the claims. Dimensions of components and features illustrated in the figures are chosen primarily for convenience and clarity of presentation and are not necessarily to scale. Referring to the attached figures:

FIG. 1 is a block diagram illustrating a fan device according to an example.

FIG. 2 is a perspective view illustrating a fan device according to an example.

FIG. 3 is a perspective view illustrating an acoustic absorption member of the fan device of FIG. 2 according to an example.

FIGS. 4A and 4B are schematic views illustrating a portion of the fan device of FIG. 2 according to examples.

FIG. 5 is a block diagram illustrating a fan assembly according to an example.

FIG. 6 is a schematic view illustrating a computing device including the fan assembly of FIG. 5 according to an example.

FIG. 7 is a flowchart illustrating a method of operating a fan device according to an example.

### DETAILED DESCRIPTION

Fan devices include vanes that rotate to move air. Computing devices include fans. Computing devices generate heat while in operation. The temperature of the computing devices may increase with higher processing speeds and processing additional processing tasks. The fans generate and direct air flow, for example, to reduce the heat from the computing systems. Accordingly, the fans may reduce the temperature of the computing devices to enable user comfort, high processing speeds, and additional processing tasks. Typically, when the fan device is in operation, rotation of the vanes push air creating turbulent air proximate to the tip ends of the vanes. The turbulent air generates sound wave energy at the tip ends of the vanes resulting in noise. Thus, the noise created by fan operation is increased due to increased sound wave energy at the tip ends of the vanes.

In examples, a fan device includes a main member, vanes, and an acoustic absorption member. The main member rotates about a point. The vanes are coupled to and extend outward from the main member. The acoustic absorption member is coupled to each one of the vanes. The acoustic absorption member and the vanes move along with the main member. The acoustic absorption member absorbs sound wave energy when sound waves collide with it. Part of the absorbed energy may be transformed into heat and part may be further transmitted. Thus, when the fan device is in operation, the air pushed by the rotation of the vanes proximate to the tip ends passes through the acoustic absorption member in contact therewith and maintains sufficient airflow. Further, the sound wave energy is absorbed by the acoustic absorptive member. For example, the sound wave energy may be transferred to heat due to the boundary layer and friction. Thus, the noise created by fan operation may be reduced.

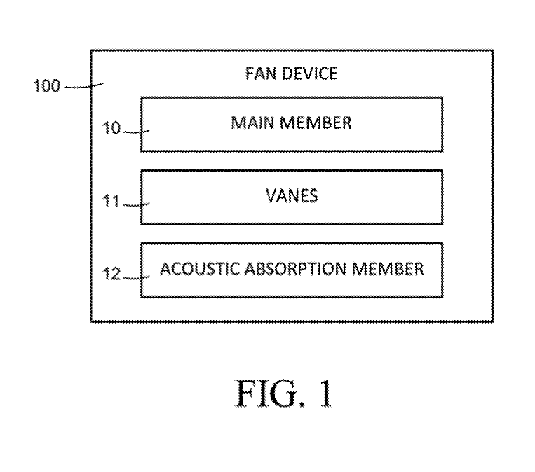

FIG. 1 is a block diagram illustrating a fan device according to an example. Referring to FIG. 1, in some examples, a fan device 100 includes a main member 10, a plurality of vanes 11, and an acoustic absorption member 12. In operation, the main member 10 may rotate about a point. For example, the point may be a longitudinal axis of a rotating shaft, and the like. The plurality of vanes 11 are coupled to and extend outward from the main member 10. In operation, the vanes 11 rotate along with the main member 10. The acoustic absorption member 12 is coupled to each one of the plurality of vanes 11. The acoustic absorption member 12 moves along with the plurality of vanes 11. Thus, when the fan device 100 is in operation, the air pushed by the rotation of the vanes 11 passes through the acoustic absorption member 12 in contact therewith. Thus, the sound wave energy is absorbed by the acoustic absorptive member 12. Accordingly, the noise created by fan operation may be reduced.

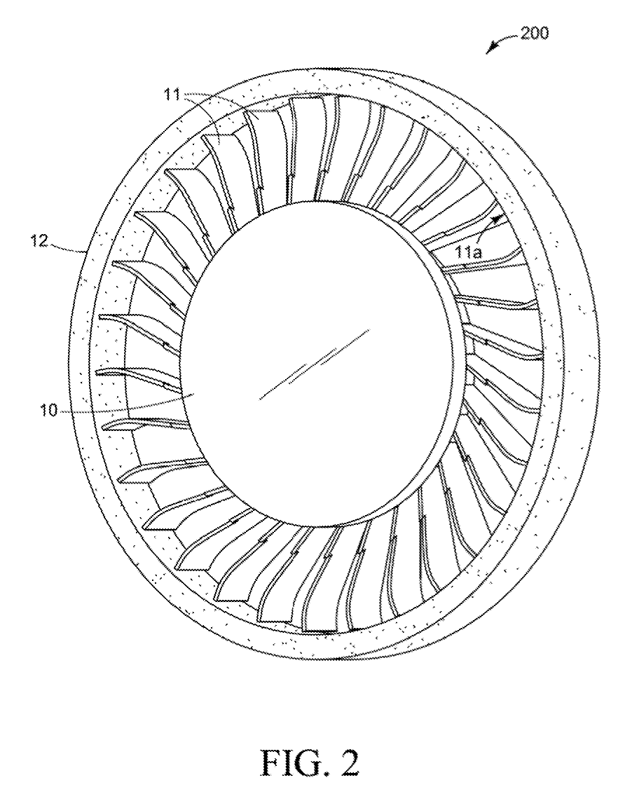

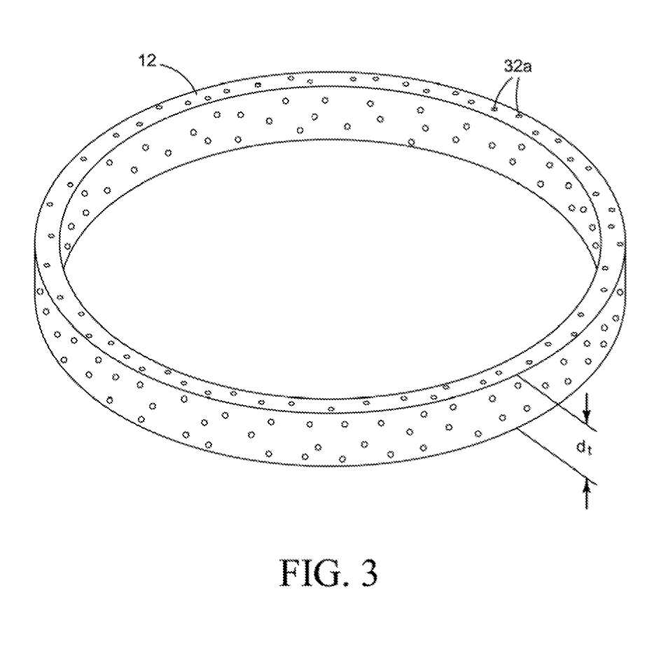

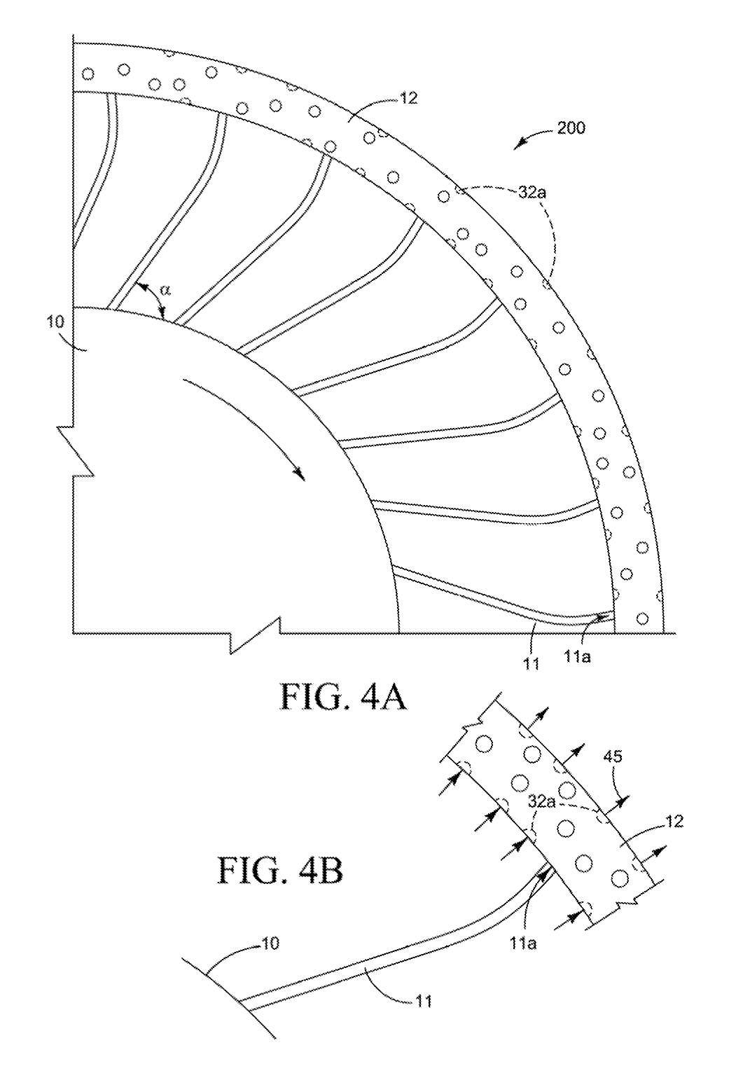

FIG. 2 is a perspective view illustrating a fan device according to an example. FIG. 3 is a perspective view illustrating an acoustic absorption member of the fan device of FIG. 2 according to an example. FIGS. 4A and 4B are schematic view illustrating a portion of the fan device of FIG. 2 according to an example. Referring to FIGS. 2-4B, in some examples, a fan device 200 includes the main member 10, the plurality of vanes 11, and the acoustic absorption member 12 as previously discussed with respect to the fan device 100 of FIG. 1. In some examples, the main member 10 and the plurality of vanes 11 are integrally formed a unitary member. For example the vanes 11 extend outward from the main member 10 at an angle α

Referring to FIGS. 2-4B, in some examples, the acoustic absorption member 12 includes a circular, acoustic absorption member surrounding and in contact with the plurality of vanes 11. For example, each one of the vanes 11 includes a corresponding tip end 11a. Each one of the corresponding tip ends 11a is in contact with the acoustic absorption member 12. The acoustic absorption member 12 may include a porous material. In some examples, the porous material may have porosity in a range of 20% to 70%. In some examples, the porous material may have a thickness dₜ that corresponds to a height of a respective vane 11. Alternatively, in some examples, the porous material may have a thickness dₜ that does not correspond to a height of a respective vane 11. Referring to FIGS. 2-4B, in some examples, the acoustic absorption member 12 includes foam, polyurethane, and the like.

Referring to FIGS. 2-4B, in operation of the fan device 200, the vanes 11 and the circular, acoustic absorption member 12 rotate in synchronous with the main member 10. As a result, the fan device 200 pushes air 45 by the rotation of the vanes 11 proximate to the tip ends 11a thereof. The air 45 passes through the acoustic absorption member 12 in contact with the tip ends 11a of the vanes 11 and maintains sufficient air flow. For example, the acoustic absorption member 12 may be directly attached to the tip ends 11a of the vanes 11. Thus, air 45 is prevented from getting between the tip ends 11a and the acoustic absorption member 12. Accordingly, sound wave energy proximate to the tip ends 11a caused by turbulent air is absorbed by the acoustic absorption member 12 and, thus, reduces noise.

For example, the air 45 may pass through pores 32a of the acoustic absorption member 12. Further, the sound wave energy produced by the turbulent air is absorbed by the acoustic absorptive member 12. The sound wave energy may be transferred to heat due to the boundary layer and friction. For example, the sound wave contacts the acoustic absorption member 12 as it moves through the porous material thereof. At least a portion of the sound wave energy is transferred into heat due to the contact between the sound wave and the acoustic absorption member 12. Thus, the noise created by operation of the fan device 200 may be reduced.

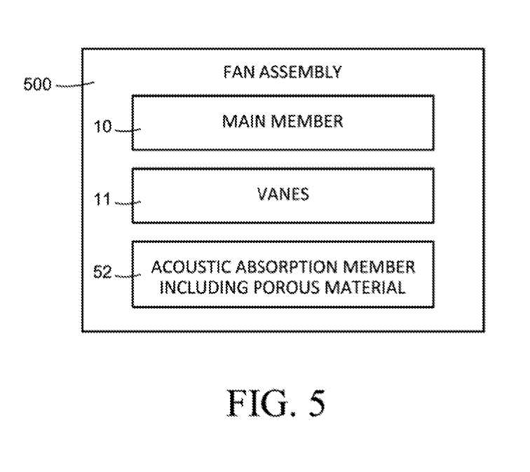

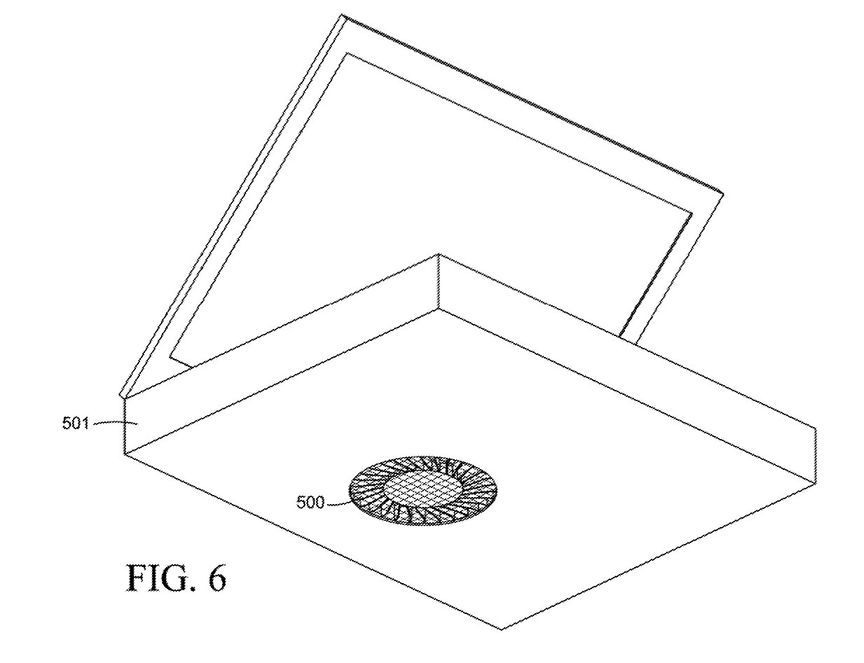

FIG. 5 is a block diagram illustrating a fan assembly according to an example. FIG. 6 is a schematic view illustrating a computing device including the fan assembly of FIG. 5 according to an example. A fan assembly 500 may be usable with a computing device 501. In operation, the fan assembly 500 may move air in the computing device 501 to remove heat therefrom. For example, hot air within a housing of the computing device 501 may be directed outside of e housing of the computing device 501. Referring to FIGS. 5 and 6, in some examples, the fan assembly 500 may include a main member 10, and vanes 11.

The main member 10 rotates about a point. For example, the main member 10 may rotate about a longitudinal axis of a rotatable shaft, and the like. The plurality of vanes 11 are coupled to and extend outward from the main member 10. For example, the vanes 11 may include impellor blades, and the like. The fan assembly 500 also includes an acoustic, absorption member 52. The acoustic absorption member 52 surrounds and is in contact with the plurality of vanes 11. The acoustic absorption member 52 includes a porous material. The vanes 11 and the acoustic absorption member 52 rotate in synchronous with the main member 10.

Referring to FIGS. 5 and 6, in some example, the acoustic absorption member 52 includes a circular, acoustic absorption member surrounding and in contact with the plurality of vanes 11. For example, each one of the vanes 11 includes a corresponding tip end 11a. Each one of the corresponding tip ends 11a is in contact with the circular, acoustic absorption member. For example, the acoustic absorption member 52 may be directly attached to the tip ends 11a of the vanes 11. Thus, air pushed by the rotating vanes 11 is prevented from getting between the tip ends 11a and the acoustic absorption member 52. Thus, sound wave energy proximate to the tip ends 11a used by turbulent air is absorbed by the acoustic absorption member 52 and, thus, reduces noise.

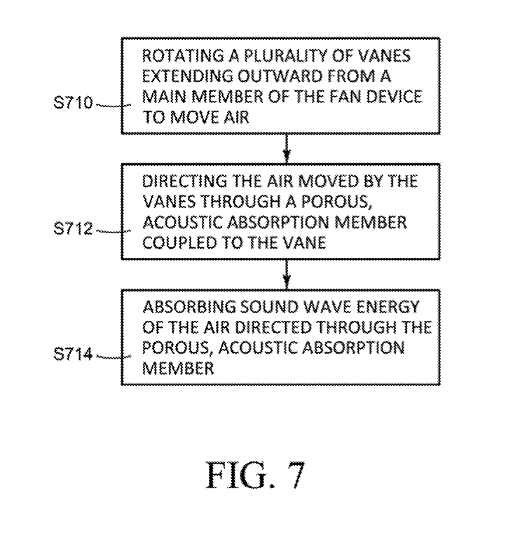

FIG. 7 is a flowchart illustrating a method of operating a fan device according to an example. In block S710, vanes extend outward from a main member of the fan device rotate to move air. In block S712, the air moved by the vanes is directed through a porous, acoustic absorption member coupled to the vanes. For example, the air moved by the vanes is directed into and out of the porous, acoustic absorption member. Additionally, the air moved through the vanes may have an air flow rate within a predetermined air flow rate range. In some example, the predetermined air flow rate may be based on a size of the vanes, a rotating speed of the vanes, and an angle in which the vanes extend outward from the main member. In some examples, the porous, acoustic absorption member may include a circular, acoustic absorption member surrounding and in contact with the plurality of vanes. Each one of the vanes may include a corresponding tip end. Each one of the corresponding tip ends may be in contact with the porous, acoustic absorption member. That is, the acoustic absorption member may be directly attached to the tip ends of the vanes.

In block S714, sound wave energy of the air directed through the porous, acoustic absorption member is absorbed therein. For example, the sound wave energy absorbed by the porous, acoustic absorption member coupled to the vanes is converted into heat. For example, the sound wave contacts the acoustic absorption member as it moves through the porous material thereof. At least a portion of the sound wave energy is transferred into heat due to the contact between the sound wave and the acoustic absorption member.

It is to be understood that the flowchart of FIG. 7 illustrates architecture, functionality, and/or operation of examples of the present disclosure. If embodied in software, each block may represent a module, segment, or portion of code that includes one or more executable instructions to implement the specified logical function(s). If embodied in hardware, each block may represent a circuit or a number of interconnected circuits to implement the specified logical function(s). Although the flowchart of FIG illustrates a specific order execution, the order of execution may differ from that which is depicted. For example, the order of execution of two or more blocks may be rearranged relative to the order illustrated. Also, two or more blocks illustrated in succession in FIG. 7 may be executed concurrently or with partial concurrence. All such variations are within the scope of the present disclosure.

The present disclosure has been described using non-limiting detailed descriptions of examples thereof that are not intended to limit the scope of the general inventive concept. It should be understood that features and/or operations described with respect to one example may be used with other examples and that not all examples have all of the features and/or operations illustrated in a particular figure or described with respect to one of the examples. Variations of examples described will occur to persons of the art. Furthermore, the terms “comprise,” “include,” “have” and their conjugates, shall mean, when used in the disclosure and/or claims, “including but not necessarily limited to.”

It is noted that some of the above described examples may include structure, acts or details of structures and acts that may not be essential to the general inventive concept and which are described for illustrative purposes. Structure and acts described herein are replaceable by equivalents, which perform the same function, even if the structure or acts are different, as known in the art. Therefore, the scope of the general inventive concept is limited only by the elements and limitations as used in the claims.

What is claimed is:

1. A fan device, comprising:
a main member to rotate about a point;
a plurality of vanes coupled to and extending outward from the member, the vanes to rotate along with the main member; and
an acoustic absorption member coupled to each one of the plurality of vanes, the acoustic absorption member to move along with the plurality of vanes.

2. The fan device of claim 1, wherein the acoustic absorption member comprises:
a circular, acoustic absorption member surrounding and in contact with the plurality of vanes.

3. The fan device of claim 1, wherein each one of the vanes includes a corresponding tip end, each one of the corresponding tip ends is in contact with the acoustic absorption member.

4. The fan device of claim 1, wherein the acoustic absorption member comprises:
a porous material.

5. The fan device of claim 1, wherein the acoustic absorption member comprises foam.

6. The fan device of claim 1, wherein the acoustic absorption member comprises polyurethane.

7. The fan device of claim 1, wherein the main member and the plurality of vanes are integrally formed as a unity member.

8. A fan assembly usable with a computing device, the fan assembly comprising:
a main member to rotate about a point;
a plurality of vanes coupled to and extending outward from the main member, and
an acoustic absorption member surrounding and in contact with the plurality of vanes, the acoustic absorption member including a porous material; and
wherein the vanes and the circular, acoustic absorption member rotate in synchronous with the main member.

9. The fan assembly of claim 8, wherein the acoustic absorption member comprises:
a circular, acoustic absorption member surrounding and in contact with the plurality of vanes.

10. The fan assembly of claim 9, wherein each one of the vanes includes a corresponding tip end, each one of the corresponding tip ends is in contact with the circular, acoustic absorption member.

11. A method of operating a fan device, the method comprising:
rotating a plurality of vanes extending outward from a main member of the fan device to move air;
directing the air moved by the vanes through a porous, acoustic absorption member coupled to the vanes; and
absorbing sound wave energy of the air directed through the porous, acoustic absorption member to reduce noised caused by operation of the fan device.

12. The method of claim 11, wherein the absorbing sound wave energy of the air directed through the porous, acoustic absorption member further comprises:
converting the sound wave energy absorbed by the porous, acoustic absorption member coupled to the vanes into heat.

13. The method of claim 11, wherein the directing the air moved by the vanes through a porous, acoustic absorption member coupled to the vanes further comprises:
directing the air moved by the varies into and out of the porous, acoustic absorption member having an air flow rate within a predetermined air flow rate range.

14. The method of claim 11, wherein the porous, acoustic absorption member comprises:
a circular, acoustic absorption member surrounding and in contact with the plurality of vanes.

15. The method of claim 11, wherein each one of the vanes includes a corresponding tip end, each one of the corresponding tip ends is in contact with the porous, acoustic absorption member.
